(19) United States
(12) Patent Application Publication
(10) Pub. No.: US 2006/0138396 A1
(43) Pub. Date: Jun. 29, 2006

(54) Quantum-dot infrared photodetector

(75) Inventors: Shih-Yen Lin, Hsinchu (TW); Jim-Yung Chi, Hsinchu (TW); Shu-Ting Chou, Hsinchu (TW); Cheng-Xuan Tsai, Hsinchu (TW)

Correspondence Address: BIRCH STEWART KOLASCH & BIRCH, PO BOX 747, FALLS CHURCH, VA, 22040-0747, US

(73) Assignee: INDUSTRIAL TECHNOLOGY RESEARCH INSTITUTE

(21) Appl. No.: 11/201,158

(22) Filed: Aug. 11, 2005

(30) Foreign Application Priority Data
Dec. 29, 2004 (TW) 93141218

(51) Int. Cl. H01L 29/06

(52) U.S. Cl. 257/13

(57) ABSTRACT

A quantum-dot infrared photodetector comprises a semiconductor substrate; a buffer layer formed on the semiconductor substrate; an undoped first obstructing layer formed on the buffer layer; a first quantum-dot layer formed on the first barrier layer; a heavily doped first contact layer formed on the first quantum-dot layer; a second quantum-dot layer formed on the first contact layer; an undoped second obstructing layer formed on the second quantum-dot layer; and a doped second contact layer formed on the second quantum-dot layer. In another embodiment, the first obstructing layer and the second obstructing layer may be formed optionally. The quantum-dot photodetector may increase photo current and constrict dark current such that detectability is improved and the operation temperature can be increased.

This application claims the benefit of Taiwan Patent Application No. 93141218, filed on Dec. 29, 2004, which is hereby incorporated by reference for all purposes as if fully set forth herein.

### BACKGROUND

1. Field of Invention

The invention relates to a quantum-dot infrared photodetector, and in particular to a quantum-dot infrared photodetector having a quantum dot transistor.

2. Related Art

Many quantum-dot infrared photodetectors have been introduced recently because of the maturity of Molecular Beam Epitaxy technology and the increasing need for infrared photodetectors. Because of the selectivity of polarization of the incident light and short life time of the excited electrons, the operation temperature of the infrared photodetector is usually lower than 100K.

Therefore, quantum-dot infrared photodetectors have been disclosed, for example, Patent Application Publication No. 20020094597. This application substitutes Gallium Arsenide quantum dots with indium arsenide quantum dots. The AlGaAs obstructing layers with a high energy gap are also formed on the two surfaces of the multi-layer quantum dots such that the electrons, which are excited from the quantum dots, accumulate within the layers owing to obstruction of the two AlGaAs obstructing layers. The electrons do not fall back into the quantum dots because of the obstruction of the higher barrier. Thus, the life time for the photo-excited electrons pairs increases because the electrons are blocked by the higher energy barrier. The photo-excited electrons accumulate to a very large scale such that the quasi Fermi level is increased. Thus the infrared photodetector may operate in high temperature.

Although the operation temperature of the quantum-dot infrared photodetector disclosed in application No. 20020094597 may increase to 250K, the photo current and the dark current may be constricted simultaneously. Thus, the detectability and response are reduced.

For laser applications, the emitting efficiency is higher because of the three-dimensional quantum confinement effect of the excitons in the quantum dots. Thus, the quantum dots laser has lower current density that starts oscillation and may be operated in higher temperature. For infrared photodetector applications, because there is no selectivity of polarization of the incident light, it is easily applicable without a complicated photo coupling mechanism. Furthermore, with the trend of increasing density of components, the quantum dots become a very important method for implementing electronic components.

The prior art does not disclose an effective solution to the problem of operating the infrared photodetector at high temperature. Therefore, there is a need to disclose a new quantum-dot infrared photodetector to operate at high temperature.

### SUMMARY

Accordingly, the invention is related to a quantum-dot infrared photodetector that substantially obviates one or more of the problems of the related art.

The disclosed quantum dot infrared photodector employs an NPN type structure, not an NIN structure as disclosed in the prior art, such that the disclosed photodetector may operate at high temperature

In one aspect, the disclosed quantum dot photodector includes a semiconductor substrate; a buffer layer formed on the semiconductor substrate; an undoped first obstructing layer formed on the buffer layer; a first quantum dot layer formed on the first barrier layer; a heavily doped first contact layer formed on the first quantum dot layer; a second quantum dot layer formed on the first contact layer; an undoped second obstructing layer formed on the second quantum dot layer; and a doped second contact layer formed on the second obstructing layer.

In another aspect, the disclosed quantum dot photodector includes a semiconductor substrate; a buffer layer formed on the semiconductor substrate; an undoped first obstructing layer formed on the buffer layer; a first quantum dot layer formed on the first barrier layer; a heavily doped first contact layer formed on the first quantum dot layer; a second quantum dot layer formed on the first contact layer; and a doped second contact layer formed on the second quantum dot layer.

In another aspect, the disclosed quantum dot photodector includes a semiconductor substrate; a buffer layer formed on the semiconductor substrate; a first quantum dot layer formed on the buffer layer; a heavily doped first contact layer formed on the first quantum dot layer; a second quantum dot layer formed on the first contact layer; an undoped second obstructing layer formed on the second quantum dot layer; and a doped second contact layer formed on the second obstructing layer.

In yet another aspect, the disclosed quantum dot photodector includes a semiconductor substrate; a buffer layer formed on the semiconductor substrate; a first quantum dot layer formed on the buffer layer; a heavily doped first contact layer formed on the first quantum dot layer; a second quantum dot layer formed on the first contact layer; and a doped second contact layer formed on the second quantum dot layer.

The infrared detector of the prior art operates in low temperature (˜77K). By employing the NPN structure in the photodector, the disclosed quantum dots photodector may increase photo current and constrict dark current such that detectability is improved and the operation temperature is increased.

In the following description, for purposes of explanation, numerous specific details are set forth in order to provide a thorough understanding of the invention. It will be apparent, however, to one skilled in the art that the invention can be practiced without these specific details. In other instances, structures and devices are shown in block diagram form in order to avoid obscuring the invention.

### BRIEF DESCRIPTION OF THE DRAWINGS

The above and other objects, features and other advantages of the invention will be more clearly understood from the following detailed description when taken in conjunction with the accompanying drawings, in which:

FIG. 1 illustrates the structure of the first embodiment of the quantum dot infrared photodetector in accordance with the invention;

FIG. 2 illustrates the structure of the second embodiment of the quantum dot infrared photodetector in accordance with the invention;

FIG. 3 illustrates the structure of the third embodiment of the quantum dot infrared photodetector in accordance with the invention;

FIG. 4 illustrates the structure of the fourth embodiment of the quantum dot infrared photodetector in accordance with the invention;

FIG. 5 illustrates the voltage-current characteristics of the quantum dot infrared photodetector in accordance with the invention;

FIG. 6 illustrates the voltage-current characteristics of the quantum dot infrared photodetector in accordance with the invention;

FIG. 7 illustrates the frequency response of low temperature and positive bias of the quantum dot infrared photodetector in accordance with the invention;

FIG. 8 illustrates the frequency response of low temperature and zero bias of the quantum dot infrared photodetector in accordance with the invention; and

FIG. 9 illustrates the frequency response of low temperature and positive bias of the quantum dot infrared photodetector in accordance with the invention.

### DETAILED DESCRIPTION

Reference will now be made in greater detail to a preferred embodiment of the invention, an example of which is illustrated in the accompanying drawings. Wherever possible, the same reference numerals are used throughout the drawings and the description to refer to the same or like parts. Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

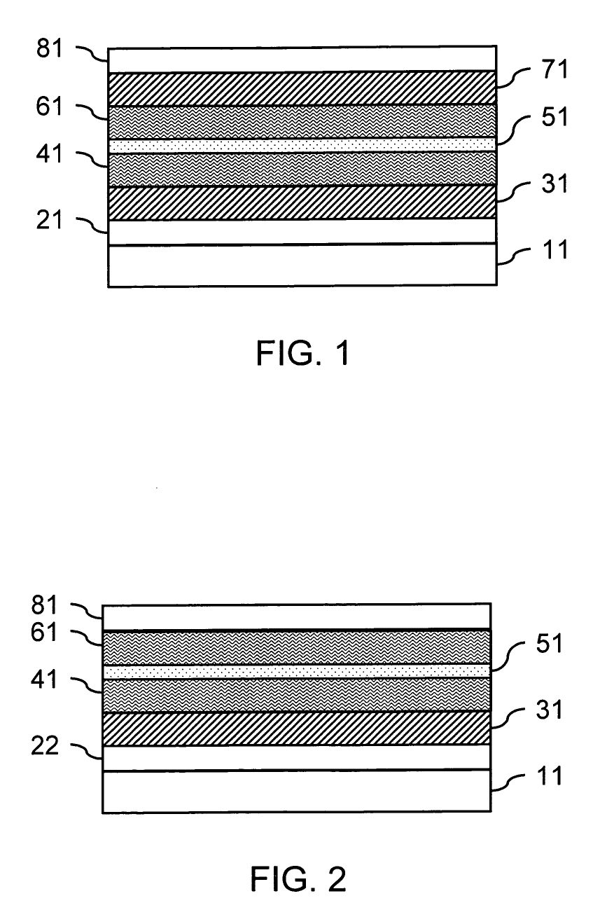

Refer to FIG. 1 illustrating the structure of the quantum dot infrared photodetector in accordance with the invention. The photodector is formed on a semiconductor substrate 11, which may be an undoped Gallium Arsenide substrate. The photodector further includes a buffer layer 21, a first obstructing layer 31, a first quantum dot layer 41, a first contact layer 51, a second quantum dot layer 61, a second obstructing layer 71, and a second contact layer 81. The details of the composition are illustrated in the following.

The doped buffer 21 is formed on the semiconductor substrate 11 as a buffer and contact layer. The buffer layer 21 may be Gallium Arsenide doped with N type IV group elements. The undoped first obstructing layer 31 is formed on the buffer layer 21. The first obstructing layer 31 may be AlGaAs with a high energy gap. The aluminum content is about 10%˜100%. The thickness of the first obstructing layer is about 10 nm˜50 nm.

The first quantum dot layer 41 is formed on the first obstructing layer 41 by way of multiple layers. The process involves forming a doped first barrier layer, whose thickness is about 10 nm˜50 nm in high temperature, e.g., 580˜620 degrees Celsius. The first barrier layer may be Gallium Arsenide doped with P type III group elements. Then InGaAs quantum dots are formed in multiple layers such that a multi-layer quantum-dot layer 41 is formed. In one embodiment, the quantum dot structure may be undoped InGaAs quantum dots. In another embodiment, the quantum dots structure may be InGaAs quantum dots doped with N type IV group elements. In another embodiment, the quantum dots structure may be Si/Ge/Si.

The heavily doped first contact layer 51 is formed on the first quantum-dot layer 41, the thickness of which is 0.1 μm˜0.5 μm. The first contact layer 51 may be Gallium Arsenide heavily doped with N type IV group elements.

The second quantum-dot layer 61 is formed on the first contact layer 51 by the same way of forming the first quantum-dot layer 51. The InGaAs quantum dots are buried in the doped second barrier layer with higher energy, whose thickness is about 10 nm˜50 nm. The second-barrier layer may be Gallium Arsenide doped with P type III group elements. In one embodiment, the second quantum-dot structure may be undoped InGaAs quantum dots. In another embodiment, the second quantum dots structure may be InGaAs quantum dots doped with N type IV group elements. In another embodiment, the second quantum dots structure may be Si/Ge/Si.

The undoped second barrier layer 71 is formed on the second quantum-dot layer 61 with a thickness of 10 nm˜50 nm. The undoped second barrier layer 71 is AlGaAs having a high energy gap, in which the aluminum content is between 10%˜100%. The doped second contact layer 81 is formed on the second quantum-dot layer 61. The layer 81 may be N type Gallium Arsenide doped with N type IV group elements to contact with other components.

The manufacturing process of the quantum-dot photodetector in accordance with the invention is given as follows. The order of the steps is not completely unchangeable. Some steps can be performed simultaneously, omitted, or added. The steps outlined herein describe the characteristics of the invention broadly and simply and are not intended to restrict the order and the number of times a particular step should be performed.

First, the buffer layer 21 of N type Gallium Arsenide is formed on an undoped semiconductor substrate 11 by way of Molecular Beam Epitaxy (MBE) to be a buffer layer and a bottom contact layer. Then an undoped AlGaAs layer with a high energy gap is formed as a first obstructing layer 31 having a thickness of 10 nm˜50 nm. The aluminum content in the AlGaAs layer is about 10%˜100%.

Then a first quantum-dot layer 41 is formed on the first obstructing layer 31. The layer 41 is formed by way of first forming a first barrier layer of P type Gallium Arsenide with a thickness of 10 nm˜50 nm under a high temperature of about 580˜620 degrees Celsius. Then, InGaAs quantum dots are buried in the first barrier layer by multiple layers. In one embodiment, the quantum-dot structure may be undoped InGaAs quantum dots. In another embodiment, the quantum-dot structure may be InGaAs quantum dots doped with N type IV group elements. In another embodiment, the quantum-dot structure may be Si/Ge/Si.

The first contact layer 51 of heavily doped P type Gallium Arsenide is formed as a base contact layer. The layer 51 has a thickness between 0.1 μm˜0.5 μm. Then the first quantum-dot layer 61 is formed by way of forming a second barrier layer of P type Gallium Arsenide with a thickness of 10 nm˜50 nm under high temperature of about 580˜620 degrees Celsius. Then, InGaAs quantum dots are buried in the second barrier layer by multiple layers. In one embodiment, the quantum-dot structure may be undoped InGaAs quantum dots. In another embodiment, the quantum-dot structure may be InGaAs quantum dots doped with N type IV group elements. In another embodiment, the quantum-dot structure may be Si/Ge/Si.

Afterward, an undoped AlGaAs layer with a high energy gap is formed as a second obstructing layer 71 having a thickness of 10 nm˜50 nm. The aluminum content in the AlGaAs layer is about 10%˜100%. A second contact layer 71 of N type Gallium Arsenide is formed as a surface contact layer.

Molecular Beam Epitaxy technology employed to manufacture the infrared photodetector has the advantage that formation may be controlled within one mono-layer. Furthermore, large area production (e.g., larger than 2 inches) is realized. Selectivity of polarization of the incident light does not have to be considered. Besides, the operation temperature of the infrared photodetector is increased through proper structural implementation. Therefore, the infrared photodetector manufactured by Molecular Beam Epitaxy technology has better operation characteristics than that manufactured in other ways.

Refer to FIG. 2 illustrating the second embodiment of the invention. The photodetector is formed on a semiconductor substrate 12. The photodetector further includes a buffer layer 22, a first obstructing layer 32, a first quantum-dot layer 42, a first contact layer 52, a second quantum-dot layer 62, and a second contact layer 82.

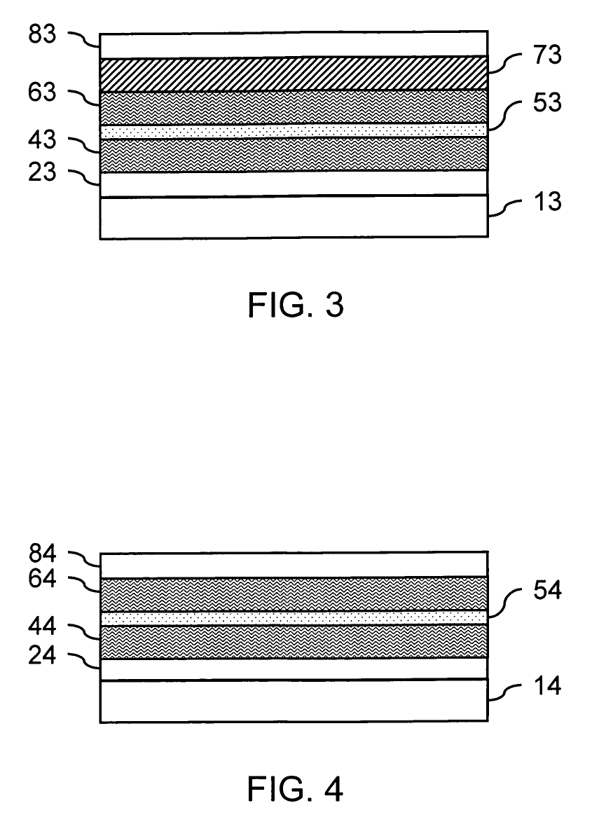

Refer to FIG. 3 illustrating the third embodiment of the invention. The photodetector is formed on a semiconductor substrate 13. The photodetector further includes a buffer layer 23, a first quantum-dot layer 43, a first contact layer 53, a second quantum-dot layer 63, a second obstructing layer 73, and a second contact layer 83.

Refer to FIG. 4 illustrating the fourth embodiment of the invention. The photodetector is formed on a semiconductor substrate 14. The photodetector further includes a buffer layer 24, a first quantum-dot layer 44, a first contact layer 54, a second quantum-dot layer 64, and a second contact layer 84.

In the second embodiment to the forth embodiment, the elements having the same or similar names with those in the first embodiment have the same composition and function as those in the first embodiment. And the manufacturing process is also the same or similar to that of the first embodiment. Related description is omitted for simplicity.

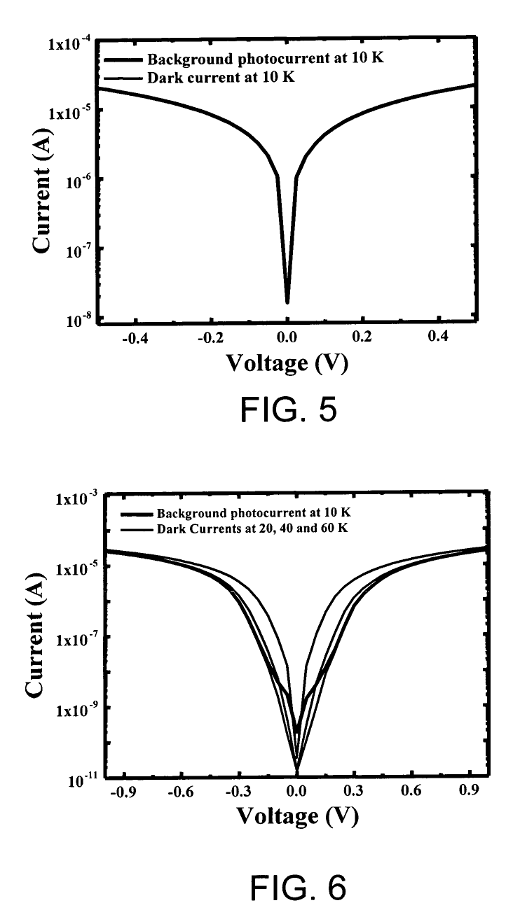

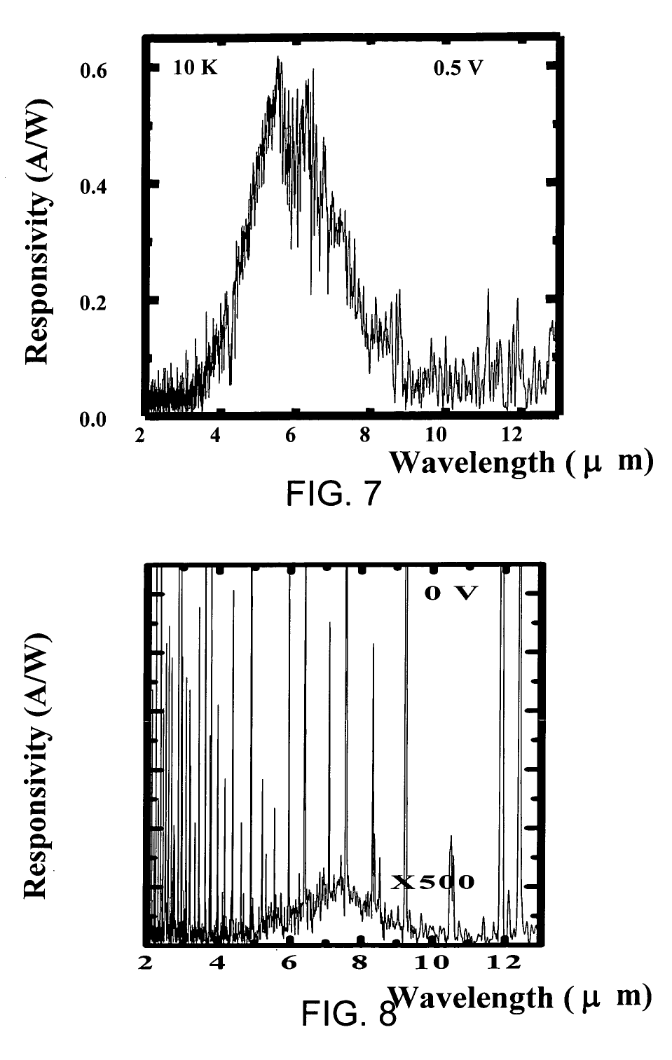

The voltage-current characteristics of the disclosed quantum-dot infrared photodetector are testified by two samples, A and B, the results of which are illustrated in FIG. 5 and FIG. 6.

TABLE I

| composition | Sample A | Sample B |
|---|---|---|
| Semiconductor substrate | 350 μm GaAs | 350 μm GaAs |
| Buffer layer | 1000 nm GaAs | 1000 nm GaAs |
| | n = 1 × 10¹⁸ cm-3 | n = 1 × 10¹⁸ cm-3 |
| First obstructing layer | 30 nm GaAs | 30 nm GaAs |
| | undoped | p = 1 × 10¹⁶ cm-3 |
| First quantum-dot layer | 2.14 ML InAs | 2.14 ML InAs |
| (5 layers) | n = 5 × 10¹⁷ cm-3 | n = 5 × 10¹⁷ cm-3 |
| Second obstructing layer | 30 nm GaAs | 30 nm GaAs |
| | undoped | p = 1 × 10¹⁶ cm-3 |
| Second contact layer | 500 nm GaAs | 500 nm GaAs |
| | n = 1 × 10¹⁸ cm-3 | n = 1 × 10¹⁸ cm-3 |

It can be seen in FIG. 5 that the photo current of SAMPE B is still lager than the dark current at a temperature of 60K. This indicates that the temperature of the background limited infrared photoconductor (BLIP) is lager than 60K. In FIG. 6, the photo current of SAMPLE A overlaps with the dark current at 10K, which indicates that the temperature of the background limited infrared photoconductor is lower than 60K. Thus, the disclosed quantum-dot infrared photodetector with an NPN transistor structure may improve operation at high temperatures.

The spectral response may be obtained through a fast Fourier-Transform Spectrometer and low current amplifier. It can be seen in FIG. 7 and FIG. 8 that the disclosed quantum-dot infrared photodetector is a PC-PV type infrared photodector under low temperature. Compared with the photo conductivity reaction, the photo voltage reaction is smaller because of the symmetry of the device.

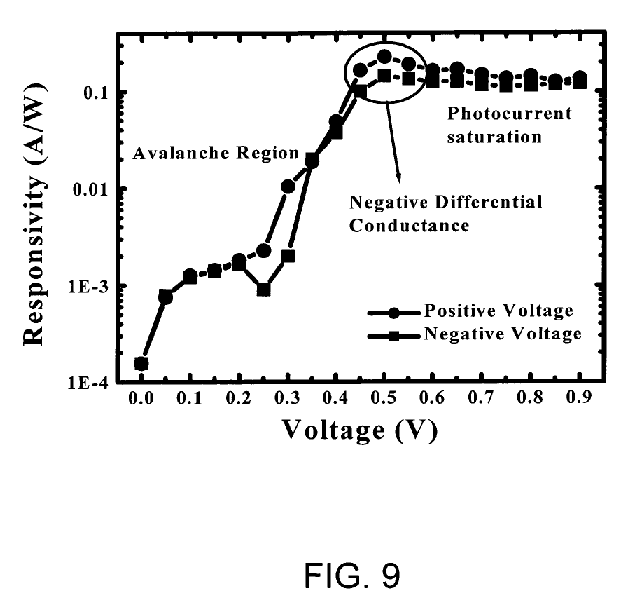

FIG. 9 illustrates the spectral response of low temperature and positive bias of the quantum-dot infrared photodetector in accordance with the invention. For the five-layer quantum dots, negative resistance and photo current saturation may occur owing to the largely imposed electric field when the photo current passes the avalanche region. This is because of the intervalley scattering of the photo electrons in the Gallium Arsenide barrier layer.

Furthermore, it can be seen in FIG. 9 that the peak response and the detectability are 0.23 A/W and 1.2×10⁹ cm·Hz1/2/W, respectively. Thus, the response and the detectability may be greatly increased, and the characteristics are sustained under high temperature with the increase of quantum dot layers.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A quantum dot infrared photodector, comprising:
a semiconductor substrate;
a buffer layer formed on the semiconductor substrate;
an undoped first obstructing layer formed on the buffer layer;
a first quantum dot layer formed on the first obstructing layer;
a heavily doped first contact layer formed on the first quantum dot layer;
a second quantum dot layer formed on the first contact layer;
an undoped second obstructing layer formed on the second quantum dot layer; and
a doped second contact layer formed on the second obstructing layer.

2. The quantum dot infrared photodector of claim 1, wherein the semiconductor substrate is an undoped Gallium Arsenide substrate.

3. The quantum dot infrared photodector of claim 1, wherein the buffer layer is Gallium Arsenide doped with N type IV group elements.

4. The quantum dot infrared photodector of claim 1, wherein the first obstructing layer is AlGaAs with high energy gap and the aluminium content is about 10%˜100%.

5. The quantum dot infrared photodector of claim 4, wherein the thickness of the first obstructing layer is about 10 nm˜50 nm.

6. The quantum dot infrared photodector of claim 1, wherein the first quantum dot layer comprises:
a doped first barrier layer; and
a plurality of quantum dots embedded in the first barrier layer.

7. The quantum dot infrared photodector of claim 6, wherein the first barrier layer is Gallium Arsenide doped with P type III group elements.

8. The quantum dot infrared photodector of claim 6, wherein the quantum dots comprises about 3˜100 layers.

9. The quantum dot infrared photodector of claim 6, wherein the quantum dots are undoped Gallium Arsenide quantum dots.

10. The quantum dot infrared photodector of claim 6, wherein the quantum dots are Gallium Arsenide quantum dots doped with N type IV group elements.

11. The quantum dot infrared photodector of claim 6, wherein the quantum dots are Si/Ge/Si.

12. The quantum dot infrared photodector of claim 1, wherein the first contact layer is Gallium Arsenide doped with heavy P type III group elements.

13. The quantum dot infrared photodector of claim 12, wherein the thickness of the first contact layer is about 0.1 μm˜0.5 μm.

14. The quantum dot infrared photodector of claim 1, wherein the second quantum dot layer comprises:
a doped second barrier layer; and
a plurality of quantum dots embedded in the second barrier layer.

15. The quantum dot infrared photodector of claim 14, wherein the second barrier layer is Gallium Arsenide doped with P type III group elements.

16. The quantum dot infrared photodector of claim 14, wherein the quantum dots comprises about 3˜100 layers.

17. The quantum dot infrared photodector of claim 14, wherein the quantum dots are undoped Gallium Arsenide quantum dots.

18. The quantum dot infrared photodector of claim 14, wherein the quantum dots are Gallium Arsenide quantum dots doped with N type IV group elements.

19. The quantum dot infrared photodector of claim 14, wherein the quantum dots are Si/Ge/Si.

20. The quantum dot infrared photodector of claim 1, wherein the second obstructing layer is AlGaAs with high energy gap and the aluminium content is about 10%˜100%.

21. The quantum dot infrared photodector of claim 20, wherein the thickness of the second obstructing layer is about 10 nm˜50 nm.

22. The quantum dot infrared photodector of claim 1, wherein the second contact layer is Gallium Arsenide doped with heavy N type IV group elements.
